(19) United States
(12) Patent Application Publication
(10) Pub. No.: US 2007/0132111 A1
(43) Pub. Date: Jun. 14, 2007

(54) FINE-SIZED CHIP PACKAGE STRUCTURE

(75) Inventor: Jeffrey Lien, Shih-Lin District, Taipei City (TW)

Correspondence Address: OPTIMUM CARE INTERNATIONAL TECH. INC., P.O. BOX 108-00403, TAIPEI, TW

(73) Assignee: OPTIMUM CARE INTERNATIONAL TECH. INC., Taipei City (TW)

(21) Appl. No.: 11/548,704

(22) Filed: Oct. 12, 2006

Related U.S. Application Data
(63) Continuation-in-part of application No. 10/959,192, filed on Oct. 7, 2004, now abandoned.

(51) Int. Cl. H01L 23/28

(52) U.S. Cl. 257/787; 257/E23.116

(57) ABSTRACT

A fine-sized chip package structure is disclosed to include a memory chip, a leadframe having a plurality of leads bilaterally arranged on the bottom surface of the memory chip, gold wires connected between respective bonding pads at the middle part of the bottom surface of the memory chip and respective stitches at the bottom surface of each rectangular block-like lead of the leadframe, and a molding compound locally molded on a part of the memory chip and a part of each leadframe with a difference of elevation between the bottom surface of the molding compound and the bottom surfaces of the leads of the leadframe for receiving a solder material used to bond the memory chip and the leadframe to a circuit board, preventing overflow of the solder material during bonding of the memory chip and the leadframe to the circuit board.

This application is a Continuation-In-Part of my patent application, Ser. No. 10/959,192, filed on Oct. 7, 2004.

### BACKGROUND OF THE INVENTION

1. Field of the Invention

The present invention relates to semiconductor packaging and more particularly, to a fine-sized chip package structure, which has the molding compound locally molded on a part of the memory chip and a part of each leadframe, leaving a different of elevation between the bottom surface of the molding compound and the bottom surfaces of the leads of the leadframe for receiving a solder material used to bond the memory chip and the leadframe to a circuit board, preventing overflow of the solder material during bonding of the memory chip and the leadframe to the circuit board and reducing the height of the chip package structure.

2. Description of the Related Art

Following the design tendency of electronic products toward light, thin, short and small characteristics and providing multi-function, high capacity (high memory capacity) and high transmission speed features, functional chips for electronic products are required to be small-sized. In consequence, memory chips for computer are developed toward mini-sized and high pin count package to reduce circuit board space occupation so that a big number of memory chips can be installed in a limited circuit board. Under the requirement for high pin count packaging, a memory chip use a big number of gold wires and lead frames for connection to a circuit board for output of a big amount of signals at a high speed. In consequence, the bonding of the leads of leadframe to a circuit board is complicated.

A leadframe works as connection means between a memory chip and an external circuit board in a semiconductor packaging process. It is a requisite passive component in a memory chip package. FIGS. 9 and 10 are schematic bottom and sectional side views of a chip package structure according to the prior art. According to this design, the leadframe A each have a plurality of leads A1, the chip B is mounted on the leads A1, and gold wires C are respectively connected between the respective bonding pad at the chip B and the leads A1 of the leadframe A for enabling the chip B to be electrically connected to an external circuit board through the leadframe A. Further, a molding compound D is molded on the chip B and the leadframe A to encapsulate the chip B and the gold wires C. According to this design, the whole chip B and the gold wires C are completely embedded in the molding compound D, resulting in a big size of the chip package structure. Further, the leads A1 of the leadframe A must be processed into a predetermined shape through a secondary processing process. Further, it is difficult to control leveling of the bonding surfaces A11 of the leads A1 that are to be bonded to the circuit board. If the leveling of the bonding surfaces A11 of the leads A1 is not well controlled, an insufficient soldering problem may occur, thereby causing a low transmission performance or a signal transmission error. Further, this design increases the material and processing cost. Further, embedding the chip B completely in the molding compound D lowers the heat dissipation efficiency of the chip package structure.

FIG. 11 shows another design of chip package structure according to the prior art. According to this design, the leadframe A are made by means of stamping or etching to provide a bottom recess A12. After the chip B is placed on the leadframe A, gold wires C are respectively connected between the chip B and the bottom recesses A12 of the leadframe A, and then the molding compound D is molded on the chip B and the leadframe A to fill up the bottom recess A12 of each leadframe A and to have the chip B and the leadframe A be embedded in the molding compound D. Further, the leads A1 of the leadframe A have bumps A13 disposed in flush with the outer surface of the molding compound D for bonding to a circuit board. This design needs to etch or stamp the leads A1 of the leadframe A to provide the desired bottom recesses A12 and bumps A13 before packaging. This secondary etching or stamping procedure greatly increases the manufacturing cost of the chip package structure. During bonding, the molten solder material may flow over the co-plane of the leads A1, causing overflow of the solder material between leads A1. Further, when the soldering points of the circuit board are changed, the leads A1 must be etched or stamped against to provide bumps A13 at locations subject to the soldering points of the circuit board. In consequence, the mold cost and the manufacturing cost are relatively increased.

Further, newly developed memory chips provide a relatively higher transmission speed. These newly developed memory chips produce a relatively higher temperature during operation. Having the chip B completely embedded in the molding compound D affects heat dissipation performance of the chip B.

Therefore, it is desirable to provide a fine-chip package structure that eliminates the aforesaid problems.

### SUMMARY OF THE INVENTION

The present invention has been accomplished under the circumstances in view. It is therefore the main object of the present invention to provide a fine-sized chip package structure, which eliminates the aforesaid drawbacks.

According to one aspect of the present invention, the fine-sized chip package structure comprises a memory chip, a leadframe have a plurality of leads bilaterally arranged on the bottom surface of the memory chip, gold wires connected between respective bonding pads at the middle part of the bottom surface of the memory chip and respective stitches at the bottom surface of each rectangular block-like lead of the leadframe, and a molding compound locally molded on a part of the memory chip and a part of each leadframe with a difference of elevation between the bottom surface of the molding compound and the bottom surfaces of the leads of the leadframe for receiving a solder material used to bond the memory chip and the leadframe to a circuit board, preventing overflow of the solder material during bonding of the memory chip and the leadframe to the circuit board.

According to another aspect of the present invention, the leads of the lead frames are rectangular metal blocks for direct bonding of the gold wires. It is not necessary to make bumps at the bottom surfaces of the leads through a complicated processing process or to cut leads into a complicated shape. Therefore, the lead frames can easily and precisely made through a mass production process, providing a high and stable quality.

According to still another aspect of the present invention, the top surface of the memory chip is exposed to the outside for quick dissipation of heat energy after local molding of the molding compound to encapsulate the gold wires. This local molding design greatly reduces the size of the chip package structure, diminishes consumption of molding material, and improves heat dissipation efficiency of the chip package structure.

### BRIEF DESCRIPTION OF THE DRAWINGS

FIG. 1 is a schematic sectional side view showing a chip packaging process according to a first embodiment of the present invention (I).

FIG. 2 is a schematic sectional side view showing a chip packaging process according to the first embodiment of the present invention (II).

FIG. 3 is a schematic sectional side view showing a chip packaging process according to the first embodiment of the present invention (III).

FIG. 4 is a schematic sectional side view showing a chip packaging process according to the first embodiment of the present invention (IV).

FIG. 5 is a schematic sectional side view of a chip package structure constructed according to the first embodiment of the present invention.

FIG. 6 is a schematic bottom view of the chip package structure shown in FIG. 5.

FIG. 7 is a schematic sectional side view showing the chip package structure installed in a circuit board according to the first embodiment of the present invention.

FIG. 8 is a schematic sectional side view of a chip package structure in accordance with a second embodiment of the present invention.

FIG. 9 is a schematic bottom view showing a chip package structure according to the prior art.

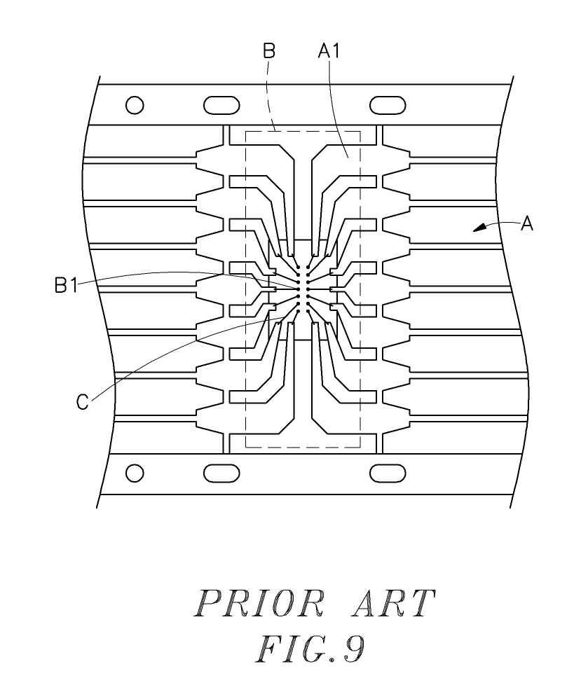

FIG. 10 is a schematic sectional side view of the chip package structure shown in FIG. 9.

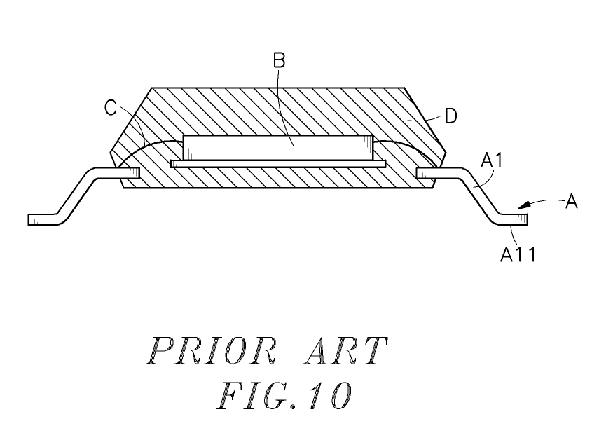

FIG. 11 is a schematic sectional side view of another chip package structure according to the prior art.

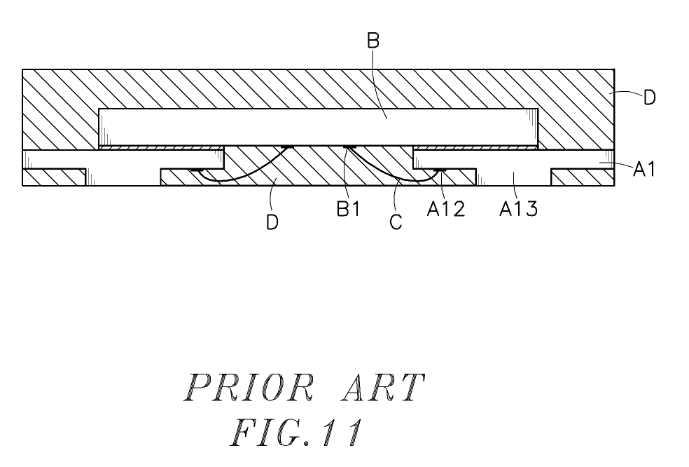

### DETAILED DESCRIPTION OF THE PREFERRED EMBODIMENT

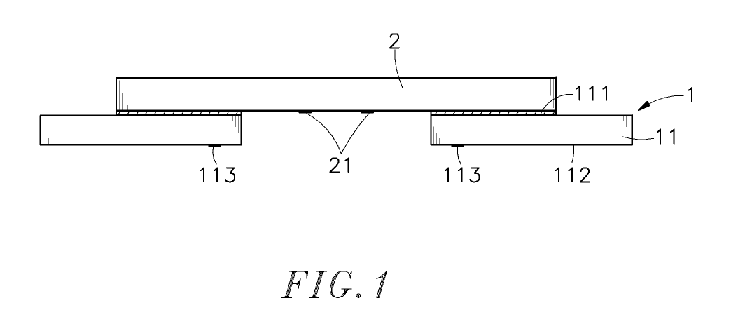

Referring to FIGS. 1-5, a fine-sized chip package structure in accordance with a first embodiment of the present invention is shown comprised of a leadframe 1, a memory chip 2, a plurality of gold wires 3 and a molding compound 4.

The leadframe 1 are arranged on the left and right sides of the memory chip 2, having a plurality of leads 11. The leads 11 are rectangular metal blocks, each having a top surface 111 adhered to the memory chip 2, and a bottom surface 112 for the bonding of the gold wires 3 for external connection. The gold wires 3 are used for electric connection between the memory chip 2 and the leads 11 of the leadframe 1.

During packaging, the leads 11 of the leadframe 1 are arranged in two rows that are respectively disposed at the left and right sides and spaced at a distance, and then two sides of the memory chip 2 are adhered to the top surfaces 111 of the leads 11 of the leadframe 1 with, for example, double-sided adhesive means (see FIG. 1), allowing the middle part of the bottom surface of the memory chip 2 beyond the leads 11 to be exposed to the outside.

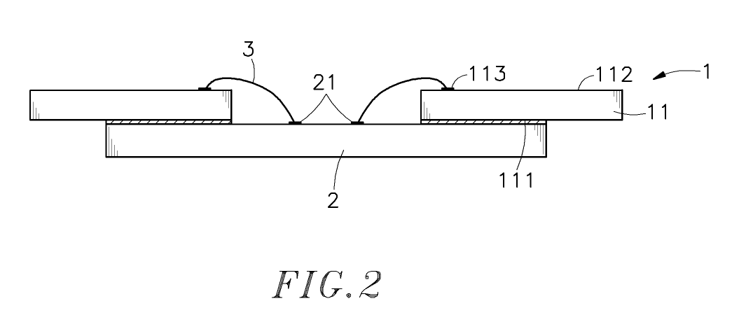

Thereafter, the memory chip 2 and the leadframe 1 are turned upside down to have the bottom surface of the memory chip 2 and the bottom surfaces 112 of the leads 11 of the leadframe 1 face upwards for wire bonding, and then the opposite ends of the gold wires 3 are respectively bonded to respective bonding pads 21 at the middle part of the bottom surface of the memory chip 2 beyond the leads 11 and respective stitches 113 at the bottom surfaces 112 of the leads 11 of the leadframe 1 (see FIG. 2).

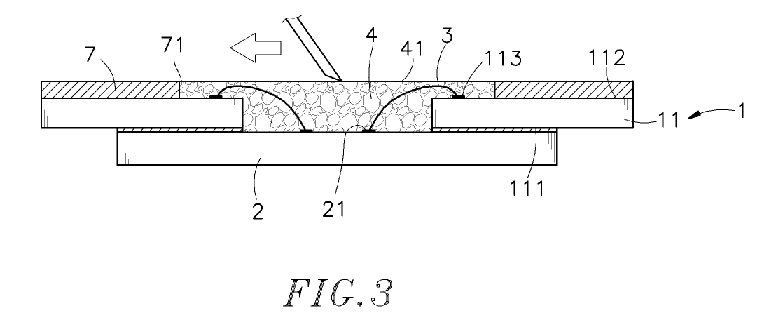

Thereafter, a mold 7 of 3 mil thickness is placed on the bottom surfaces 112 of the leads 11 of the leadframe 1 with the cavity 71 set corresponding to the connection area between the gold wires 3 and the bonding pads 21 at the middle part of the bottom surface of the memory chip 2 and the stitches 113 at the bottom surfaces 112 of the leads 11 of the leadframe 1 (see FIG. 3), and then the prepared molding compound 4 is filled in the cavity 71 of the mold 7 and molded locally on the bottom surfaces 112 of the leads 11 of the leadframe 1 and the bottom surface of the memory chip 2 to have the gold wires 3 be embedded in the molding compound 4, and then dejunk excessive part of the molding compound 4 to level a bottom surface 41 of the molding compound 4, and then remove the mold 7, and then deliver the semi-finished product thus obtained in a pressure oven for baking.

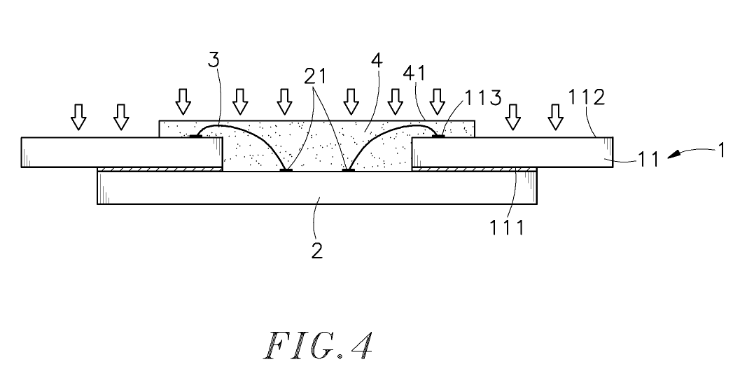

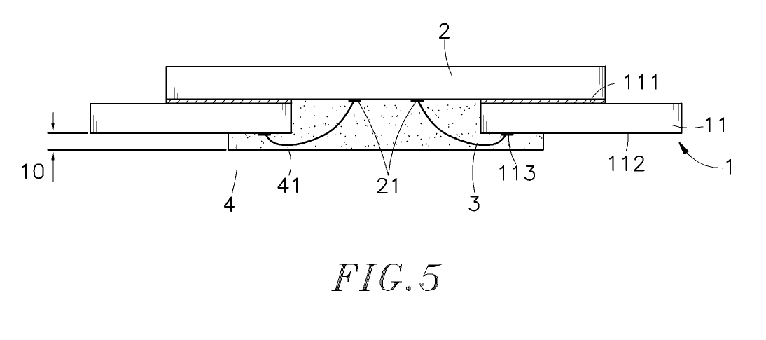

Further, because the paste-like molding compound 4 contains water and air bubbles, baking the paste-like molding compound 4 under the atmospheric pressure will cause air bubbles to protrude over the bottom surface 41 and to further make the bottom surface 41 uneven due to thermal expansion and cold contraction effects. Uneven of the bottom surface 41 of the molding compound 4 may result in an insufficient soldering problem. In order to eliminate this problem, the invention bakes the paste-like molding compound 4 in a pressure oven (not shown), i.e. the semi-finished product is delivered to a pressure oven after molding of the paste-like molding compound 4. The inside pressure of the pressure oven is controlled at about 5 times over the atmospheric pressure. Baking the molding compound 4 under this high pressure keeps air bubbles on the inside of the molding compound 4 and prohibits air bubbles from moving to the bottom surface 41 of the molding compound 4, and also enhances bonding of the molding compound 4 to the bottom surfaces 112 of the leads 11 of the leadframe 1 (see FIG. 4), thereby accurately controlling the leveling of the bottom surface 41 of the molding compound 4. After baking, the bottom surfaces 112 of the leads 11 of the leadframe 1 are partially encapsulated by the molding compound 4 and partially exposed outside the molding compound 4, and the bottom surface 41 of the molding compound 4 is disposed below the elevation of the bottom surfaces 112 of the leads 11 of the leadframe 1 (see FIG. 5), showing a difference of elevation 10 between the bottom surface 41 of the molding compound 4 and the bottom surfaces 112 of the leads 11 of the leadframe 1. This difference of elevation 10 is preferably controlled within 1-3 mil not only for accommodating the gold wires 3 connected to the stitches 113 in the molding compound 4 but also for accommodating a solder material that is used to bond the part of the bottom surfaces 112 of the leads 11 of the leadframe 1 outside the molding compound 4 to a circuit board. After bonding of the part of the bottom surfaces 112 of the leads 11 of the leadframe 1 outside the molding compound 4 to a circuit board, the desired fine-sized chip package structure is thus finished.

Further, the length of the molding compound 4 is shorter than the length of the memory chip 2 but longer than the pitch between the stitches 113 of the two leads 11 of the leadframe 1. This structural design saves much molding cost while the conducting metal wires 3 is kept embedded in the molding compound 4.

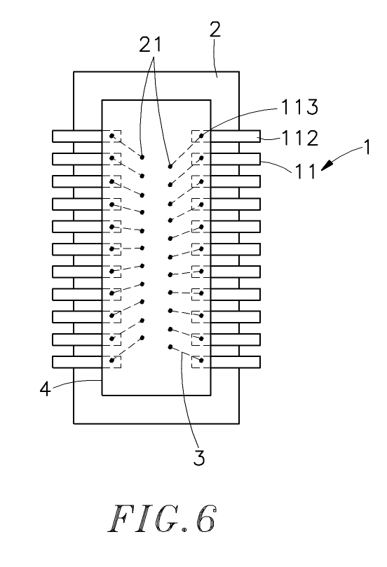

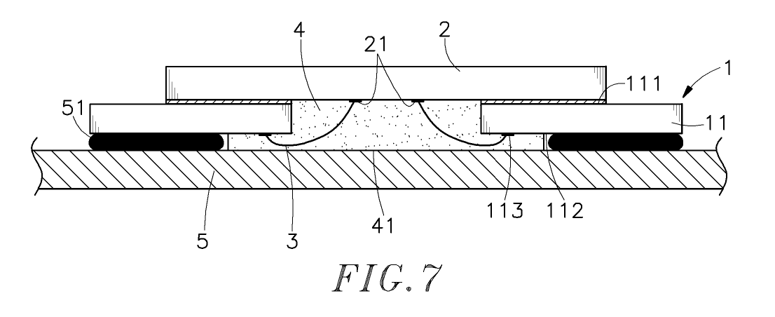

Referring to FIGS. 6 and 7 and FIG. 5 again, the leads 11 are rectangular metal blocks for direct bonding of the gold wires 3. It is not necessary to process the leads 11 (such as etching or embossing the leads to form bumps at the bottom surfaces of the leads) or to cut the leads 11 into a complicated shape. The gold wires 3 are directly bonded to respective stitches 113 at the bottom surfaces 112 of the leads 11 and respective bonding pads 21 at the bottom surface of the memory chip 2, and then the molding compound 4 is molded on the memory chip 2 and the leads 11 to encapsulate the gold wires 3, leaving a difference of elevation 10 between the bottom surface 41 of the molding compound 4 and the bottom surfaces 112 of the leads 11 of the leadframe 1. Thereafter, the part of the bottom surfaces 112 of the leads 11 of the leadframe 1 outside the molding compound 4 is bonded to a circuit board 5 with a solder material 51, which is received in the difference of elevation 10.

By means of siphon effect, the solder material 51 at the circuit board 5 fills up the space area of the difference of elevation 10 between the bottom surface 41 of the molding compound 4 and the bottom surfaces 112 of the leads 11 of the leadframe 1, preventing overflow of the molten solder material 51 during soldering and assuring positive contact of the bottom surfaces 112 of the leads 11 of the leadframe 1 with the solder material 51. The local molding of the present invention reduces the size of the chip package structure, diminishes consumption of molding material, and improves heat dissipation efficiency of the chip package structure.

Further, after local molding, the top surface of the memory chip 2 is exposed to the outside of the molding compound 4 to receive outside cold air, allowing direct and even dissipation of heat energy. Therefore, heat energy will not be accumulated in the memory chip 2. This design greatly improves the heat dissipation efficiency of the chip package structure, and reduces the height of the chip package structure.

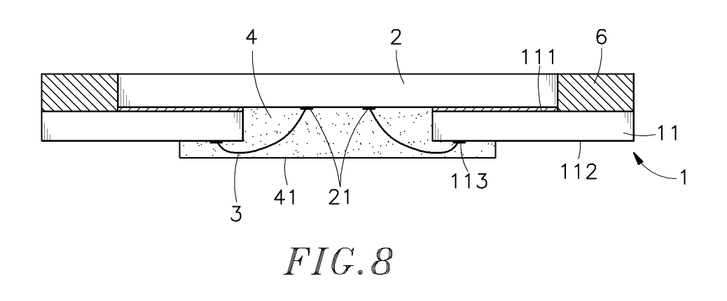

FIG. 8 shows a fine-sized chip package structure in accordance with a second embodiment of the present invention. This second embodiment is substantially similar to the aforesaid first embodiment of the present invention with the exception of an additional molding compound 6, which is molded on the top surfaces 111 of the leads 11 of the leadframe 1 around the memory chip 2 and kept in flush with the top surface of the memory chip 2. In addition to enhancing the positioning of the memory chip 2, this second embodiment provides the same various benefits as the aforesaid first embodiment.

As stated above, the invention provides a fine-sized chip package structure, which has the following benefits:

1. The molding compound 4 is molded on the memory chip 2 and the leadframe 1 to encapsulate the gold wires 3, leaving a difference of elevation 10 between the bottom surface 41 of the molding compound 4 and the bottom surfaces 112 of the leads 11 of the leadframe 1, which difference of elevation 10 causes siphon effect so that the solder material 51 at the circuit board 5 fills up the space area of the difference of elevation 10 during installation of the memory chip 2 in the circuit board 5, eliminating insufficient soldering, preventing overflow of the solder material 51, and assuring positive contact of the bottom surfaces 112 of the leads 11 of the leadframe 1 with the solder material 51.

2. The leads 11 are rectangular metal blocks for direct bonding of the gold wires 3. It is not necessary to make bumps at the bottom surfaces 112 of the leads 11 through a complicated processing process or to cut leads 11 into a complicated shape. Therefore, the leadframe 1 can easily and precisely made through a mass production process, providing a high and stable quality.

3. After local molding of the molding compound 4 to encapsulate the gold wires 3, the top surface of the memory chip 2 is exposed to the outside for quick dissipation of heat energy. This local molding design greatly reduces the size of the chip package structure, diminishes consumption of molding material, and improves heat dissipation efficiency of the chip package structure.

A prototype of fine-sized chip package structure has been constructed with the features of FIGS. 1-8. The fine-sized chip package structure functions smoothly to provide all of the features discussed earlier.

Although particular embodiments of the invention has been described in detail for purposes of illustration, various modifications and enhancements may be made without departing from the spirit and scope of the invention. Accordingly, the invention is not to be limited except as by the appended claims.

What the invention claimed is:

1. An fine-sized chip package structure comprising a memory chip, said memory chip having a top surface and a bottom surface opposite to said top surface, a leadframe having a plurality of leads symmetrically arranged on left and right sides of said memory chip, a plurality of gold wires electrically connected between said memory chip and said leads of said leadframe, and a molding compound molded on said memory chip, said leadframe and said gold wires, wherein said memory chip has a plurality of bonding pads at a middle part of said bottom surface thereof outside said leads of said leadframe;
said leads of said leadframe are rectangular metal blocks, said rectangular metal blocks each having a top surface adhered to said memory chip and a plurality of stitches at a bottom surface thereof for the bonding of said gold wires;
said gold wires each have a first end respectively bonded to said bonding pads at the middle part of said bottom surface of said memory chip beyond said leads of said leadframe and a second end respectively bonded to said stitches at said bottom surfaces of said leads of said leadframe;
said molding compound is molded on said middle part of said bottom surface of said memory chip to encapsulate said gold wires, said bonding pads of said memory chip and said stitches of said leads of said leadframe, leaving a difference of elevation between a bottom surface of said molding compound and said bottom surfaces of said leads of said leadframe for receiving a solder material to be used to bond said memory chip and said leadframe to a circuit board.

2. The fine-sized chip package structure as claimed in claim 1, wherein said different of elevation is greater than the height of said gold wires above said stitches at the bottom surfaces of said leads of said leadframe.

3. The fine-sized chip package structure as claimed in claim 1, wherein said different of elevation is within 1-3 mil.

4. The fine-sized chip package structure as claimed in claim 1, wherein a part of said bottom surfaces of said leads of said leadframe outside said molding compound is electrically connected to said solder material on said circuit board.

5. The fine-sized chip package structure as claimed in claim 1, wherein said molding compound has a length smaller than a length of said memory chip.

6. The fine-sized chip package structure as claimed in claim 1, wherein said molding compound has a length greater than a pitch between said stitches of said two leads of said leadframe.

7. The fine-sized chip package structure as claimed in claim 1, wherein said memory chip is exposed to the outside of said molding compound.

8. The fine-sized chip package structure as claimed in claim 1, wherein said molding compound is molded on said bottom surface of said leads of said leadframe and periphery of said memory chip and kept in flush with said top surface of said memory chip.
